(19) United States
(12) Patent Application Publication
(10) Pub. No.: US 2016/0043274 A1
(43) Pub. Date: Feb. 11, 2016

(54) GROUP III NITRIDE SEMICONDUCTOR LIGHT-EMITTING DEVICE AND PRODUCTION METHOD THEREFOR

(71) Applicant: TOYODA GOSEI CO., LTD., Kiyosu-shi (JP)

(72) Inventors: Toru KANTO, Kiyosu-shi (JP); Koichi GOSHONOO, Kiyosu-shi (JP)

(21) Appl. No.: 14/817,723

(22) Filed: Aug. 4, 2015

(30) Foreign Application Priority Data
Aug. 5, 2014 (JP) 2014-159506

(51) Int. Cl. H01L 33/10; H01L 33/00; H01L 33/32; H01L 33/20; G02B 5/18; H01L 33/12

(52) U.S. Cl. CPC H01L 33/10; G02B 5/1857; H01L 33/12; H01L 33/32; H01L 33/20; H01L 33/0075; H01L 2933/0025; H01L 2933/0058; H01L 2933/0033

(57) ABSTRACT

The present invention provides a Group III nitride semiconductor light-emitting device which attains suitable light extraction to the outside by reflecting the light directed from a substrate to a semiconductor layer toward the substrate, and a production method therefor. The light-emitting device comprises a substrate, a buffer layer, an n-type semiconductor layer, a light-emitting layer, a p-type semiconductor layer, and a plurality of dielectric multilayer films. The dielectric multilayer films are disposed on the first surface of the substrate. The first surface of the substrate has at least a bottom surface. The buffer layer is formed on at least a part of the bottom surface. The dielectric multilayer films have inclined planes inclined to the bottom surface. The n-type semiconductor layer is formed on the buffer layer and the inclined planes of the dielectric multilayer films.

### BACKGROUND OF THE INVENTION

1. Field of the Invention

The present invention relates to a Group III nitride semiconductor light-emitting device and a production method therefor. More particularly, the invention relates to a Group III nitride semiconductor light-emitting device having a semiconductor layer on an uneven structure and a production method therefor.

2. Background Art

In the technical field of the semiconductor light-emitting device, the techniques have been developed to efficiently extract light emitted from the light-emitting layer in order to improve the emission efficiency. For example, there is a technique to form an uneven surface on the substrate, thereby varying the transmissivity or reflectance at a boundary between the substrate and the semiconductor layer.

Japanese Patent Application Laid-Open (kokai) No. 2004-247757 discloses the technique to form an uneven refractive index interface at a position which affects light propagating in a transversal direction parallel to the surface of a substrate (refer to paragraph [0023]). It also discloses the technique to form a GaN-based crystal film having different refractive indices such as a first crystal 20a and a second crystal 20b (refer to paragraphs [0067] to and FIG. 4). With these, the light propagating in the transversal direction is directed toward the outside (refer to paragraphs [0005] to [0007], [0018], [0022] to [0023]). For example, in a flip-chip type light-emitting device, the light propagating in the transversal direction is reflected to be incident to a surface of the substrate (refer to paragraph [0006]). Thus, the technique to reflect the light toward the surface of the substrate is described.

In a flip-chip type light-emitting device, some of the light propagating through the substrate is directed from the semiconductor layer to a light extraction surface of the substrate, and the other is directed from the light extraction surface of the substrate to the semiconductor layer. Such a light is difficult to extract to the outside of the light-emitting device by the technique described in Japanese Patent Application Laid-Open (kokai) No. 2004-247757.

### SUMMARY OF THE INVENTION

The present invention has been conceived in order to solve the aforementioned technical problems involved in the conventional techniques. Thus, an object of the present invention is to provide a Group III nitride semiconductor light-emitting device which attains suitable light extraction to the outside by reflecting the light directed from the light extraction surface of the substrate to the semiconductor layer toward the substrate at an interface between the substrate and the semiconductor layer, and a production method therefor.

In a first aspect of the present technique, there is provided a Group III nitride semiconductor light-emitting device comprising:

a substrate having a first surface, a buffer layer formed on at least a part of the first surface of the substrate, a first conduction type first semiconductor layer on the buffer layer, a light-emitting layer on the first semiconductor layer, and a second conduction type second semiconductor layer on the light-emitting layer. The Group III nitride semiconductor light-emitting device has a plurality of dielectric multilayer films on the first surface side of the substrate. The first surface of the substrate has at least a flat surface. The buffer layer is formed on at least a part of the flat surface. Each of the dielectric multilayer films has an inclined plane inclined to the flat surface. The first semiconductor layer is formed on the buffer layer and the inclined planes of the dielectric multilayer films.

In the Group III nitride semiconductor light-emitting device, the surfaces of the dielectric multilayer films constitute the surfaces of protrusions. The dielectric multilayer film transmits light directed from the semiconductor layer toward the substrate, and reflects light directed from the substrate toward the semiconductor layer. Therefore, the light-emitting device can suppress the light from being reabsorbed by the light-emitting layer. The light-emitting device can efficiently extract the light emitted from the light-emitting layer to the outside.

A second aspect of the technique is drawn to a specific mode of the Group III nitride semiconductor light-emitting device, wherein, the first surface of the substrate has a plurality of protrusions. The dielectric multilayer films cover at least a part of the surfaces of the protrusions. The portion other than the protrusions on the first surface of the substrate is a flat surface.

A third aspect of the technique is drawn to a specific mode of the Group III nitride semiconductor light-emitting device, wherein, the first surface of the substrate is flat over the entire surface thereof. The flat surface is formed over the entire surface of the first surface. The buffer layer is formed on a part of the flat surface. The dielectric multilayer films are formed on the remaining portion of the flat surface, which are also the protrusions protruding toward the first semiconductor layer.

A fourth aspect of the technique is drawn to a specific mode of the Group III nitride semiconductor light-emitting device, wherein, the dielectric multilayer films are the Distributed Bragg Reflectors (DBR).

A fifth aspect of the technique is drawn to a specific mode of the Group III nitride semiconductor light-emitting device, wherein, the buffer layer is not disposed on the dielectric multilayer films.

A sixth aspect of the technique is drawn to a specific mode of the Group III nitride semiconductor light-emitting device, wherein, the Group III nitride semiconductor light-emitting device is a flip-chip type light-emitting device. The substrate has a roughened second surface. Therefore, the light once incident from the semiconductor layer to the substrate is hardly returned from the substrate to the semiconductor layer, and is extracted to the outside.

In a seventh aspect of the technique, there is provided a method for producing a Group III nitride semiconductor light-emitting device comprising:

a substrate preparation step of preparing a substrate having a first surface provided with at least a flat surface;

a buffer layer formation step of forming a buffer layer on at least a part of the flat surface;

a first semiconductor layer formation step of forming a first conduction type first semiconductor layer on the buffer layer;

a light-emitting layer formation step of forming a light-emitting layer on the first semiconductor layer; and

a second semiconductor layer formation step of forming a second conduction type second semiconductor layer on the light-emitting layer.

The production method further comprises a dielectric multilayer film formation step of forming a plurality of dielectric multilayer films on the first surface of the substrate. In the dielectric multilayer film formation step, a plurality of dielectric multilayer films having inclined planes inclined to the flat surface is formed. In the buffer layer formation step, the buffer layer is grown on the flat surface of the substrate which is not covered with the dielectric multilayer films. In the first semiconductor layer formation step, the first semiconductor layer is grown on the buffer layer so as to cover the inclined planes of the dielectric multilayer films.

An eighth aspect of the technique is drawn to a specific mode of the method for producing the Group III nitride semiconductor light-emitting device, wherein, in the substrate preparation step, a substrate having an uneven structure in which the first surface comprises a flat surface and a plurality of protrusions. The dielectric multilayer film formation step comprises a mask formation step of forming a mask, a film formation step of forming a dielectric multilayer film on the protrusions, and a mask removal step of removing the mask from the flat surface to obtain a plurality of dielectric multilayer films on the protrusions.

A ninth aspect of the technique is drawn to a specific mode of the method for producing the Group III nitride semiconductor light-emitting device, wherein, in the substrate preparation step, the flat surface is over the entire surface of the first surface. The dielectric multilayer film formation step comprises a film formation step of forming an uniform dielectric multilayer film on the flat surface, a resist disposition step of disposing a resist mask with a predetermined pattern on the uniform dielectric multilayer film, an etching step of etching the uniform dielectric multilayer film, thereby forming inclined planes, making the uniform dielectric multilayer film into a plurality of dielectric multilayer films, and partially exposing the flat surface of the substrate. In the buffer layer formation step, a buffer layer is formed on the flat surface partially exposed.

The present techniques provide a Group III nitride semiconductor light-emitting device which attains suitable light extraction to the outside by reflecting the light directed from the substrate to the semiconductor layer toward the substrate, and a production method therefor.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view of the structure of a light-emitting device according to Embodiment 1;

FIG. 2 is a view showing the structure of a dielectric multilayer film and adjacent layers of the light-emitting device according to Embodiment 1;

FIG. 3 is a view showing the structure of the dielectric multilayer film of the light-emitting device according to Embodiment 1;

FIG. 4 is a view showing the concepts of reflection and transmission in the dielectric multilayer film of the light-emitting device according to Embodiment 1;

FIG. 5 is a view (part 1) showing a substrate preparation step in a method for producing a light-emitting device according to Embodiment 1;

FIG. 6 is a view (part 2) showing a substrate preparation step in the method for producing the light-emitting device according to Embodiment 1;

FIG. 7 is a view (part 1) showing a dielectric multilayer film formation step in the light-emitting device according to Embodiment 1;

FIG. 8 is a view (part 2) showing a dielectric multilayer film formation step in the light-emitting device according to Embodiment 1;

FIG. 9 is a view showing the method for producing the light-emitting device according to Embodiment 1;

FIG. 10 is a schematic view of the structure of a light-emitting device according to Embodiment 2;

FIG. 11 is a view showing the structure of a dielectric multilayer film and adjacent layers of the light-emitting device according to Embodiment 2;

FIG. 12 is a view showing the structure of the dielectric multilayer film of the light-emitting device according to Embodiment 2;

FIG. 13 is a view showing the concepts of reflection and transmission in the dielectric multilayer film of the light-emitting device according to Embodiment 2;

FIG. 14 is a view (part 1) showing a step of forming a dielectric multilayer film in the light-emitting device according to Embodiment 2;

FIG. 15 is a view (part 2) showing a step of forming a dielectric multilayer film in the light-emitting device according to Embodiment 2;

FIG. 16 is a view (part 3) showing a step of forming a dielectric multilayer film in the light-emitting device according to Embodiment 2; and

FIG. 17 is a view (part 4) showing a step of forming a dielectric multilayer film in the light-emitting device according to Embodiment 2.

### DETAILED DESCRIPTION OF PREFERRED EMBODIMENTS

With reference to the drawings, specific embodiments of the semiconductor light-emitting device and the production method will next be described in detail. However, these embodiments should not be construed as limiting the techniques thereto. The below-described layered structure of the layers of the semiconductor light-emitting device and the electrode structure are given only for the illustration purpose, and other layered structures differing therefrom may also be employed. The thickness of each of the layers shown in the drawings is not an actual value, but a conceptual value.

### Embodiment 1

### 1. Semiconductor Light-Emitting Device

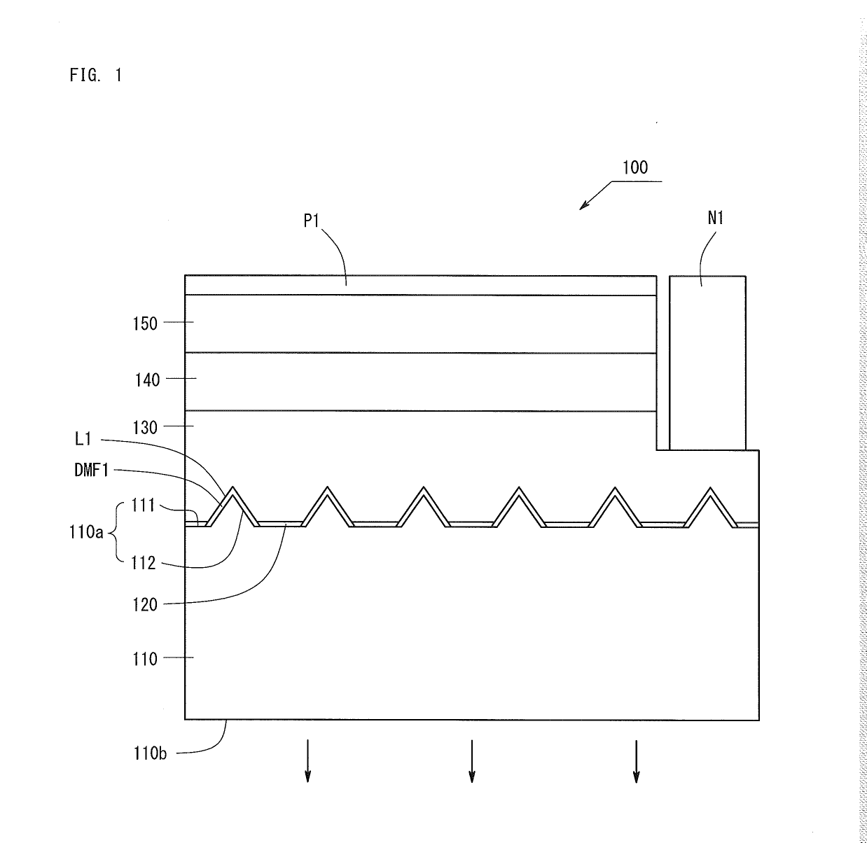

FIG. 1 is a schematic view of the structure of a light-emitting device 100 of Embodiment 1. The light-emitting device 100 is a flip-chip type semiconductor light-emitting device. In the light-emitting device 100, a light is extracted from a light extraction surface of the substrate in the direction of arrows as shown in FIG. 1. The light-emitting device 100 has a plurality of semiconductor layers formed of a Group III nitride semiconductor. As shown in FIG. 1, the light-emitting device 100 has a substrate 110, a dielectric multilayer film DMF1, a buffer layer 120, an n-type semiconductor layer 130, a light-emitting layer 140, a p-type semiconductor layer 150, an n-electrode N1, and a p-electrode P1.

As shown in FIG. 1, the substrate 110 has a first surface 110a and a second surface 110b. The first surface 110a comprises a flat bottom surface 111 and a plurality of protrusions 112. The protrusions are isolated each other like an island. The second surface 110b is a light extraction surface. The dielectric multilayer film DMF1 is formed on the protrusions 112 of the first surface 110a of the substrate 110. The buffer layer 120 is formed on the bottom surface 111 of the first surface 110a of the substrate 110. The buffer layer 120 is not disposed on the dielectric multilayer film DMF1. In FIG. 1, for convenience of drawing, an edge of the buffer layer 120 appears to hang over the ends of the dielectric multilayer film DMF1. However, actually they are hardly overlapped.

The n-type semiconductor layer 130 is formed on the buffer layer 120 and inclined planes L1 of the dielectric multilayer film DMF1. The n-type semiconductor layer 130 is a first conduction type first semiconductor layer. The light-emitting layer 140 is formed on the n-type semiconductor layer 130. The p-type semiconductor layer 150 is formed on the light-emitting layer 140. The p-type semiconductor layer 150 is a second conduction type second semiconductor layer.

The n-electrode N1 is formed on the n-type semiconductor layer 130. Therefore, the n-electrode N1 is electrically connected to the n-type semiconductor layer 130. The p-electrode P1 is formed on the p-type semiconductor layer 150. Therefore, the p-electrode P1 is electrically connected to the p-type semiconductor layer 150. The p-electrode P1 preferably serves as a reflective layer to reflect a light directed from the p-type semiconductor layer 150 toward the p-electrode P1.

### 2. Structure of Substrate and Adjacent Layers

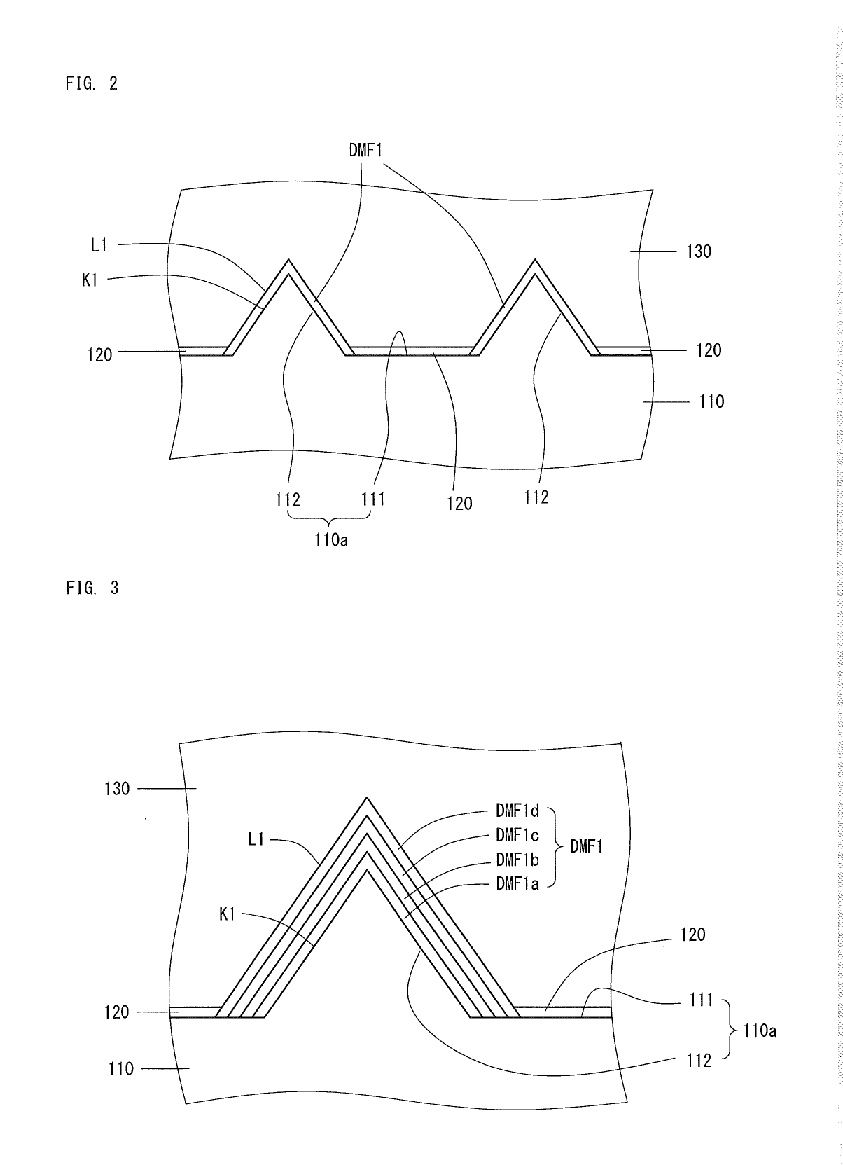

FIG. 2 is an enlarged view showing a part of the vicinity of the substrate 110. As shown in FIG. 2, the first surface 110a of the substrate 110 comprises a flat bottom surface 111 and a plurality of protrusions 112. The bottom surface 111 is a flat surface. The protrusions 112 protrude toward the n-type semiconductor layer 130. Each of the protrusions 112 has a conical shape. Each of the protrusions 112 has an inclined plane K1 inclined to the flat bottom surface 111. The inclined plane K1 is a conical surface.

As shown in FIG. 2, a plurality of dielectric multilayer films DMF1 is formed on a plurality of protrusions 112. That is, the dielectric multilayer film DMF1 covers at least a part of the surface of the protrusion. On the bottom surface 111, the dielectric multilayer film DMF1 is not formed. A portion other than the protrusions 112 of the first surface 110a of the substrate 110 is the flat bottom surface 111. An angle of the inclined plane K1 to the bottom surface 111 is within a range of 40° to 60°. The angle range is merely an example, and other angle values may be acceptable.

On the bottom surface 111, the buffer layer 120 is formed. On the buffer layer 120, the n-type semiconductor layer 130 is formed. On the inclined plane K1 of the protrusion 112, as mentioned above, the dielectric multilayer film DMF1 is formed. The dielectric multilayer film DMF1 covers the protrusion 112. Therefore, the protrusion 112 is not contacted with the n-type semiconductor layer 130.

### 3. Dielectric Multilayer Film

FIG. 3 is an enlarged view showing the vicinity of the dielectric multilayer film DMF1. As shown in FIG. 3, the dielectric multilayer film DMF1 is formed on the inclined plane K1 of the protrusion 112. Therefore, the dielectric multilayer film DMF1 has the inclined plane L1 inclined to the flat bottom surface 111. The inclined plane L1 is a conical surface. Therefore, the surface of the dielectric multilayer film DMF1 has a conical shape. The respective inclined planes L1 of the dielectric multilayer film DMF1 are almost parallel to the inclined plane K1 of the protrusion 112. On the inclined plane L1, the n-type semiconductor layer 130 is provided.

The inclined plane L1 constitutes an uneven shape disposed on the first surface 110a side of the substrate 110. The uneven shape of the dielectric multilayer film DMF1 has a height of 1 μm to 5 μm. The pitch interval of the uneven shape is 1 μm to 5 μm. The angle of the uneven shape is 40° to 60°. These values are merely examples, and other values may be employed.

The dielectric multilayer film DMF1 comprises dielectric films DMF1a, DMF1b, DMF1c, DMF1d, and so on. The dielectric multilayer film DMF1 is a Distributed Bragg Reflector (DBR). That is, the dielectric multilayer film DMF1 is formed by alternately depositing two types of dielectrics having different refractive indices. For example, the dielectric films DMF1a and DMF1c are made of TiO₂, and the dielectric films DMF1b and DMF1d are made of SiO₂. The dielectric films DMF1a, DMF1b, DMF1c, and DMF1d are inclined with respect to the bottom surface 111. The dielectric films DMF1a, DMF1b, DMF1c, and DMF1d are deposited in a direction almost perpendicular to the inclined plane K1.

The dielectric films of the dielectric multilayer film DMF1 are deposited, for example, 25 times to 41 times. FIG. 3 shows the dielectric films DMF1a, DMF1b, DMF1c, and DMF1d. However, the number of depositions of the dielectric films in the Distributed Bragg Reflector (DBR) may be other values than those described above. The number of depositions of the dielectric films is preferably an odd number, but an even number may be acceptable.

Each of the dielectric films DMF1a, DMF1b, DMF1c, and DMF1d has a thickness of, for example, 10 nm to 1,000 nm. Other thickness values of the dielectric films DMF1a, DMF1b, DMF1c, and DMF1d may be acceptable. Moreover, other material such as Al₂O₃ may be employed for the dielectric films DMF1a, DMF1b, DMF1c, and DMF1d.

### 4. Effect of Dielectric Multilayer Film

### 4-1. Transmission and Reflection In Dielectric Multilayer Film

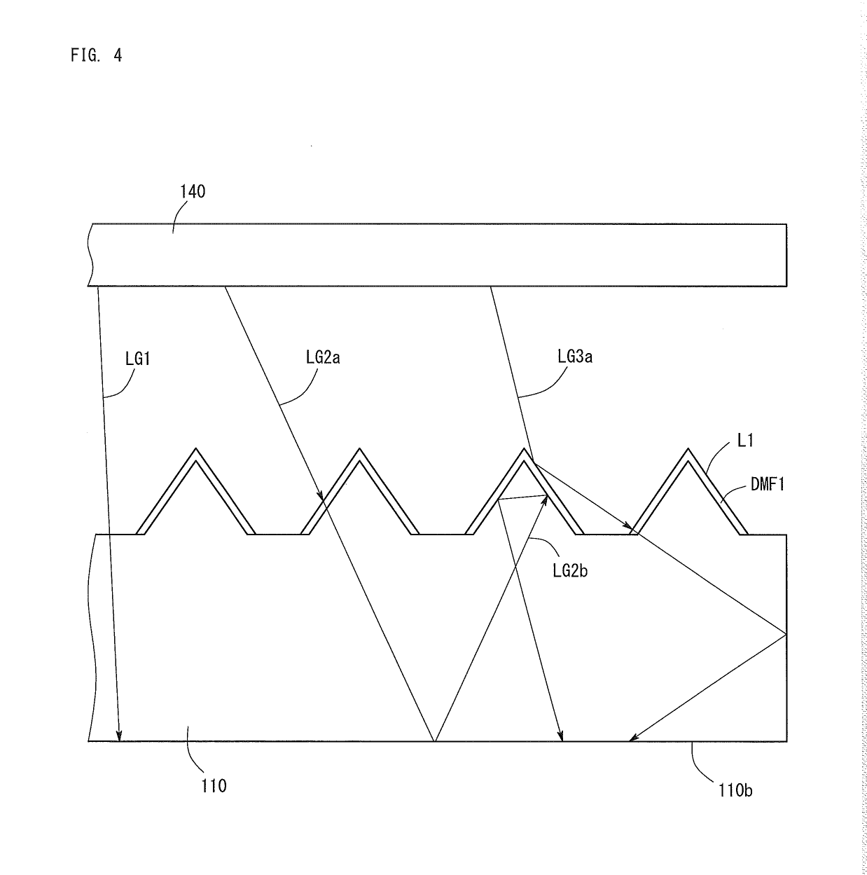

FIG. 4 is a view showing the concepts of reflection and transmission in the vicinity of the dielectric multilayer film DMF1 in the light-emitting device 100. FIG. 4 shows the substrate 110, the dielectric multilayer film DMF1, and the light-emitting layer 140 of all the components of the light-emitting device 100. As shown in FIG. 4, a light LG1 directed from the light-emitting layer 140 toward the substrate 110 is incident to a flat surface where the dielectric multilayer film DMF1 is not formed and passes through the substrate 110. The light LG1 is emitted from the second surface 110b to an outside.

A light LG2a directed from the light-emitting layer 140 toward the substrate 110, firstly passes through the dielectric multilayer film DMF1, and is incident to the substrate 110. The light LG2a is reflected by the second surface 110b and the reflected light LG2b is directed toward the light-emitting layer 140. Then, the light LG2b is reflected twice by the back surface of the dielectric multilayer film DMF1, and is directed toward the second surface 110b again. The light LG2b is emitted from the second surface 110b to an outside.

Moreover, a light LG3a directed from the light-emitting layer 140 toward the substrate 110 is firstly reflected by the dielectric multilayer film DMF1, thereafter passes through another dielectric multilayer film DMF1, and is incident to the substrate 110. The light LG3a is emitted from the second surface 110b to an outside. Thus, in Embodiment 1, even if the incident light to the dielectric multilayer film DMF1 is reflected by the dielectric multilayer film DMF1, the reflected light is incident to another dielectric multilayer film DMF1 and may pass through the dielectric multilayer film DMF1 to be incident to the substrate 110.

In this way, the light firstly incident from the semiconductor layer to the first surface 110a of the substrate 110 is hardly incident to the semiconductor layer again. Therefore, the incident light is hardly reabsorbed by the light-emitting layer 140, the semiconductor layers or other metal layer. Thus, the dielectric multilayer film DMF1 transmits more components of the light directed from the semiconductor layer toward the first surface 110a of the substrate 110, and more components of the light which are reflected at the second surface 100b of the substrate 110 and directed toward the semiconductor layer are reflected at the back surface of the dielectric multilayer film DMF1. The light reflected at the DMF1 propagates toward the light extraction surface again. From the above, the light extraction efficiency is high in the light-emitting device 100 according to Embodiment 1.

### 4-2. Calculation Results

The results of the calculation performed for the light-emitting device 100 according to Embodiment 1 will be next described. Calculation was performed for the case where the dielectric multilayer film DMF1 was formed by alternately depositing TiO₂ and SiO₂ five times. At this time, refractive index Rs for s-polarization and refractive index Rp for p-polarization were calculated with respect to the incident angle. Under the conditions of the substrate 110 according to Embodiment 1, a total radiant flux was calculated.

As the result of the calculation, the total radiant flux of the light-emitting device 100 having the dielectric multilayer film DMF1 was higher by about 3% than that of the light-emitting device 100 having no dielectric multilayer film DMF1 formed.

### 5. Method of Processing Substrate

### 5-1. Substrate Preparation Step

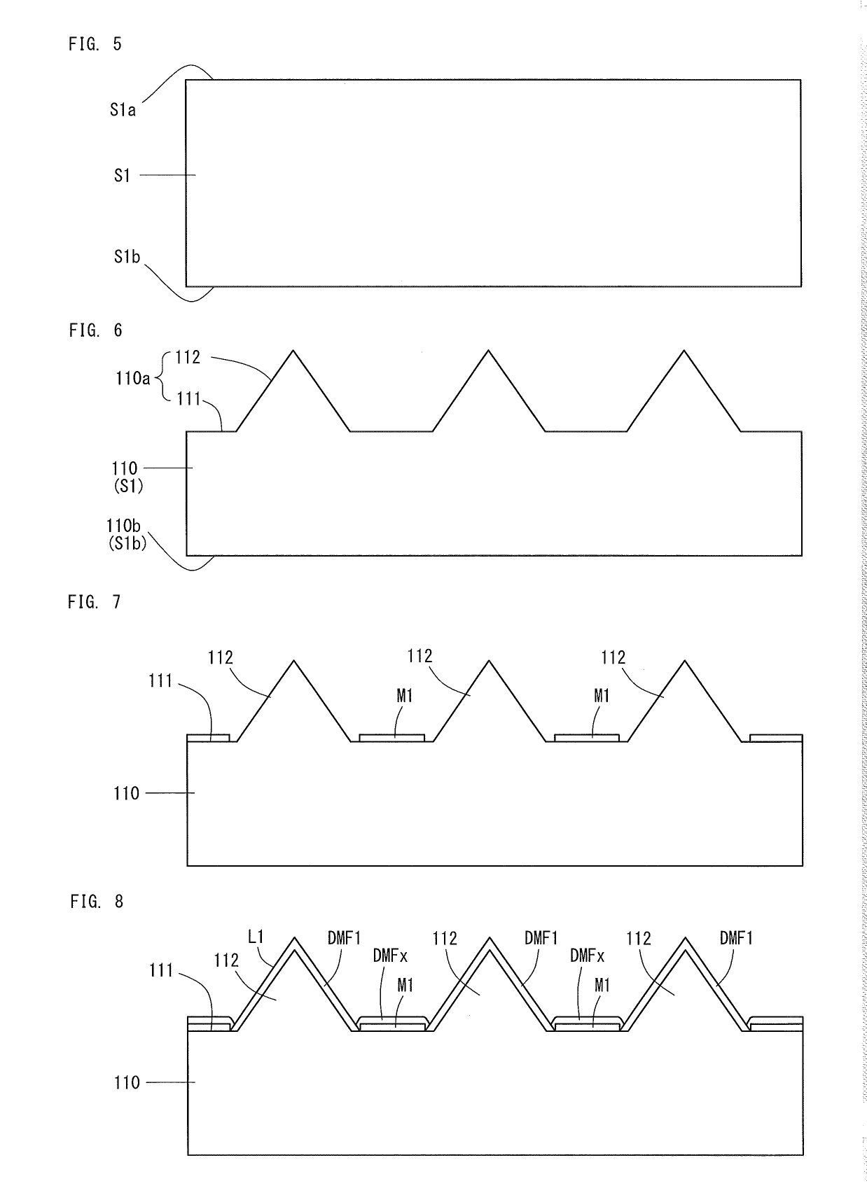

Firstly, there is provided a substrate S1 shown in FIG. 5. The substrate S1 has a flat main surface S1a and a flat second surface S1b. Subsequently, as shown in FIG. 6, the main surface S1a of the substrate S1 is roughened to form a bottom surface and a plurality of protrusions 112 to make the first surface 110a. Laser processing or etching may be employed. Through this processing, a flat bottom surface 111 and a plurality of protrusions 112 are formed on the main surface S1a of the substrate S1. In this way, the substrate 110 having an uneven structure on the first surface 110a is obtained. This processing is not required by purchasing a substrate having an uneven structure.

### 6. Method Of Forming A Dielectric Multilayer Film

The method of forming a dielectric multilayer film DMF1 according to Embodiment 1 is described. The method of forming a dielectric multilayer film DMF1 comprises a mask formation step, a film formation step, and a mask removal step.

### 6-1. Mask Formation Step

As shown in FIG. 7, a mask M1 is formed on the bottom surface 111 of the substrate 110. At this time, the mask M1 is not formed on a plurality of protrusions 112 of the substrate 110. That is, the protrusions 112 of the substrate 110 are exposed.

### 6-2. Film Formation Step

Next, as shown in FIG. 8, a dielectric multilayer film DMF1 is formed on each of the protrusions 112. The dielectric multilayer film DMF1 is formed through sputtering or a vapor deposition technique. Thus, the dielectric multilayer films DMF1 are formed along the protrusions 112. Moreover, a dielectric multilayer film DMFx is formed on the mask M1 as well.

### 6-3. Mask Removal Step

The mask M1 is removed from the bottom surface 111 of the substrate 110. That is, the mask M1 and the dielectric multilayer film DMFx formed on the mask M1 are removed. Then, the dielectric multilayer films DMF1 shown in FIG. 2 are formed. As a result, the dielectric multilayer films DMF1 are formed on the protrusions 112 of the substrate 110, and the bottom surface 111 is exposed.

### 7. Method for Producing a Semiconductor Light-Emitting Device

Next will be described a method for producing the light-emitting device 100 according to Embodiment 1. In Embodiment 1, the semiconductor crystal layers are formed through epitaxial growth based on metalorganic chemical vapor deposition (MOCVD). Examples of the carrier gas employed in the growth of semiconductor layers include hydrogen (H₂), nitrogen (N₂), and a mixture of hydrogen and nitrogen (H₂+N₂). Ammonia gas (NH₃) is used as a nitrogen source, and trimethylgallium (Ga(CH₃)₃: (TMG)) is used as a gallium source. Trimethylindium (In(CH₃)₃: (TMI) is used as an indium source, and trimethylaluminum (Al(CH₃)₃: (TMA) is used as an aluminum source. Silane (SiH₄) is used as an n-type dopant gas, and cyclopentadienylmagnesium (Mg(C₅H₅)₂) is used as a p-type dopant gas.

### 7-1. Dielectric Multilayer Film Formation Step

In the dielectric multilayer film formation step, as described above, the mask formation step, the dielectric film formation step, and the mask removal step are performed. Thus, a dielectric multilayer film DMF1 having an inclined plane L1 inclined with respect to a bottom surface 111 of a substrate 110 is formed.

### 7-2. Buffer Layer Formation Step

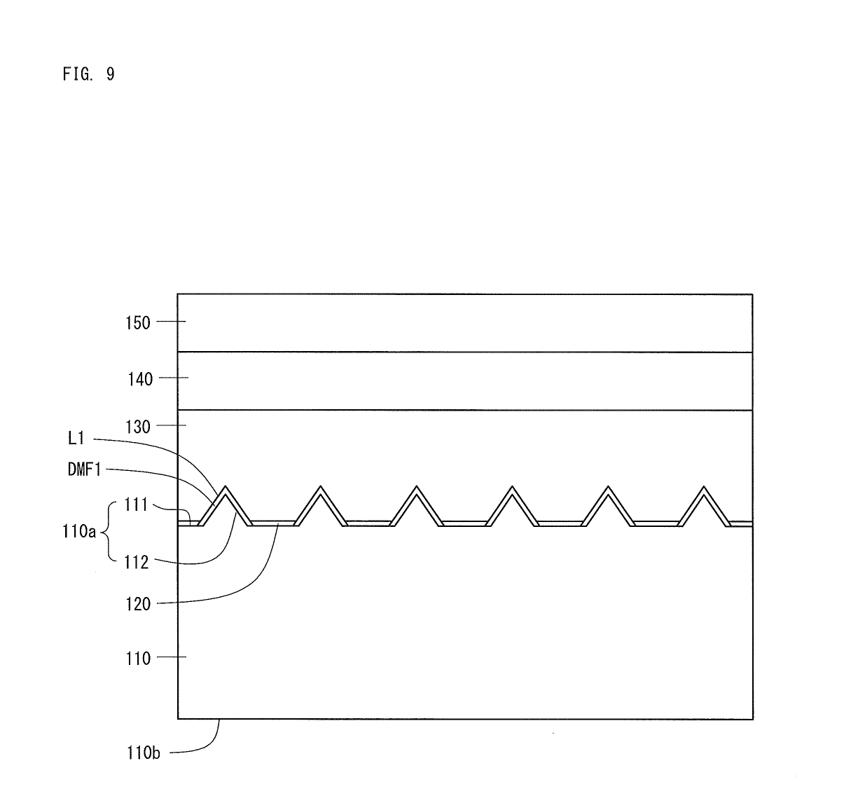

Subsequently, a buffer layer 120 is formed on the bottom surface 111 of the substrate 110. The buffer layer 120 is formed on the bottom surface 111, but is not formed on the dielectric multilayer film DMF1 (refer to FIG. 9). That is, the buffer layer 120 is grown along the bottom surface 111 from the bottom surface 111 of the substrate 110, which is not covered with the dielectric multilayer film DMF1.

### 7-3. First Semiconductor Layer Formation Step (N-Type Semiconductor Layer Formation Step)

Then, an n-type semiconductor layer 130 is formed on the buffer layer 120. The n-type semiconductor layer 130 is grown from the buffer layer 120 formed on the bottom surface 111. Then, the n-type semiconductor layer 130 is grown so as to cover the inclined plane L1 of the dielectric multilayer film DMF1. During this layer growth, the substrate temperature is within a range of 1,080° C. to 1,140° C. Silane (SiH₄) is appropriately supplied. Thus, for example, an n-type contact layer and an n-type superlattice layer are formed.

### 7-4. Light-Emitting Layer Formation Step

On the n-type semiconductor layer 130, a light-emitting layer 140 is formed. For example, an InGaN layer, a GaN layer, and an AlGaN layer are repeatedly deposited. Needless to say, other layered structure of the light-emitting layer 140 may be acceptable. In this procedure, the substrate temperature is, for example, within a range of 700° C. to 900° C.

### 7-5. Second Semiconductor Layer Formation Step (P-Type Semiconductor Layer Formation Step)

On the light-emitting layer 140, a p-type semiconductor layer 150 is formed. For example, cyclopentadienylmagnesium (Mg(C₅H₅)₂) is used as a dopant gas. For example, a p-type superlattice layer and a p-type contact layer are formed. The p-type semiconductor layer 150 after the formation is shown in FIG. 9.

### 7-6. Electrode Formation Step

Subsequently, the semiconductor layers are partially removed through laser radiation or etching from the p-type semiconductor layer 150 side, to thereby expose the n-type contact layer 130. An n-electrode N1 is formed on the thus-exposed region. A p-electrode P1 is formed on the p-type semiconductor layer 150.

### 7-7. Other Steps

In addition to the aforementioned steps, additional steps such as a step of covering the device with a protective film and a heat treatment step may be carried out. From the above, the light-emitting device 100 shown in FIG. 1 is produced.

### 8. Variation

### 8-1. Type of Light-Emitting Device

The light-emitting device 100 according to Embodiment 1 is a flip-chip type light-emitting device. However, the present techniques may be employed for a face-up type light-emitting device.

### 8-2. Conduction Type

In Embodiment 1, the first conduction type was n-type, and the second conduction type was p-type. However, the combination of conduction type may be inverted. That is, the first conduction type may be p-type, and the second conduction type may be n-type.

### 8-3. Roughening of Light Extraction Surface

The second surface 110b of the substrate 110 shown in FIG. 1 may be roughened, thereby, improving the light extraction efficiency from the second surface 110b as a light extraction surface.

### 8-4. Shape of Protrusion(s)

Each of the protrusions 112 has a conical shape. However, it may have a hexagonal pyramid shape. Moreover, it may have a truncated cone shape or hexagonal truncated pyramid shape. In this case, the dielectric multilayer film DMF1 comprises an inclined plane L1 and an upper end surface disposed at a position corresponding to the top of the protrusion 112. The n-type semiconductor layer 130 is formed on the buffer layer 120, the inclined planes, and the upper end surfaces thereof.

8-5. Substrate type

The sapphire substrate 110 was employed in Embodiment 1. Other substrate than sapphire substrate such as a GaN substrate, a GaAs substrate, and a SiC substrate may be employed.

### 9. Summary of Embodiment 1

As described hereinabove, the light-emitting device 100 according to Embodiment 1 has the dielectric multilayer films DMF1 on the protrusions 112 comprising the first surface 110a of the substrate 110. The dielectric multilayer film DMF1 transmits more light directed from the semiconductor layer toward the first surface 110a of the substrate 110, and reflects at the back surface thereof more light directed from the second surface 110b of the substrate 110 toward the semiconductor layer. Therefore, the light firstly emitted from the semiconductor layer to the first surface 110a of the substrate 110 is hardly incident to the semiconductor layer again. This achieves a light-emitting device 100 which can appropriately extract a light from the light extraction surface.

In the method for producing the semiconductor light-emitting device of Embodiment 1, the semiconductor layer is grown from the bottom surface 111 where the dielectric multilayer film DMF1 is not formed.

The aforementioned embodiment is merely an example. It is therefore understood that those skilled in the art can provide various modifications and variations of the technique, so long as those fall within the scope of the present technique. The layered structure of the layered product should not be limited to those as illustrated, and the layered structure, the number of repetition of component layers, and other factors may be arbitrarily chosen. The semiconductor layer growth technique is not limited to metalorganic chemical vapor deposition (MOCVD), and other techniques such as hydride vapor phase epitaxy (HVPE) and other liquid-phase epitaxy techniques may also be employed.

### Embodiment 2

Embodiment 2 will now be described. The substrate and the dielectric multilayer film of the light-emitting device according to Embodiment 2 differ from those of the light-emitting device according to Embodiment 1. Therefore, the substrate and the dielectric multilayer film different from Embodiment 1, and the production method therefor will be described.

### 1. Semiconductor Light-Emitting Device

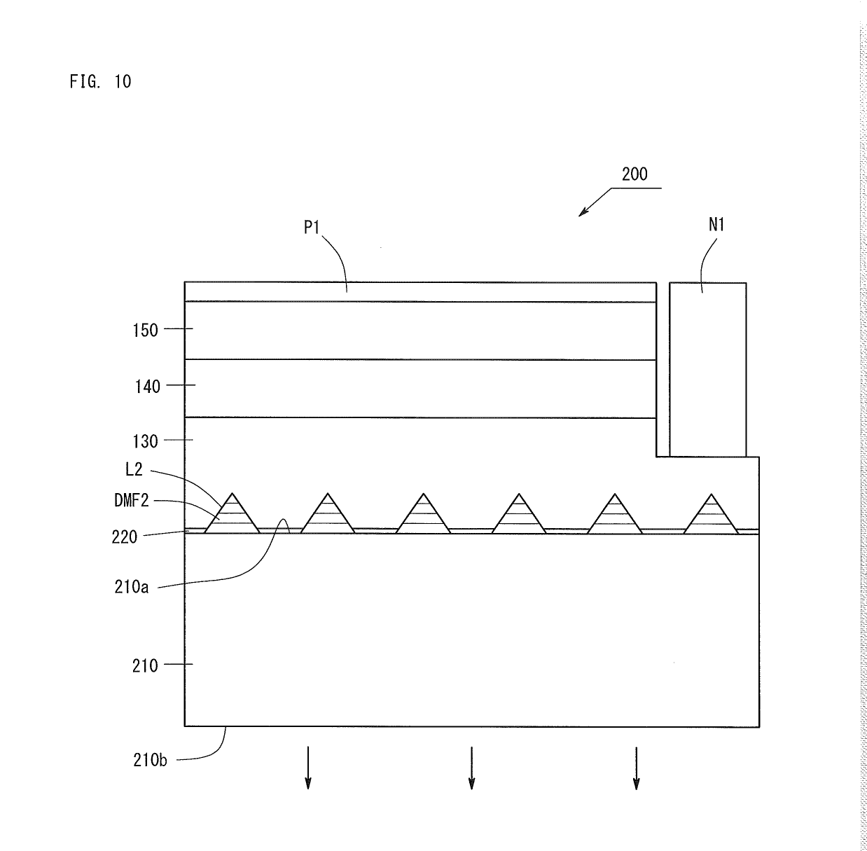

FIG. 10 is a schematic view of the structure of a light-emitting device 200 according to Embodiment 2. As shown in FIG. 10, the light-emitting device 200 has a substrate 210, a dielectric multilayer film DMF2, a buffer layer 220, an n-type semiconductor layer 130, a light-emitting layer 140, a p-type semiconductor layer 150, an n-electrode N1, and a p-electrode P1. The substrate 210 has a first surface 210a and a second surface 210b. The second surface 210b is a light extraction surface.

On the buffer layer 220, an n-type semiconductor layer 130 is formed. The n-type semiconductor layer 130 is formed on the buffer layer 220 and inclined planes L2 of the dielectric multilayer films DMF2.

### 2. Structure of Substrate and Adjacent Layers

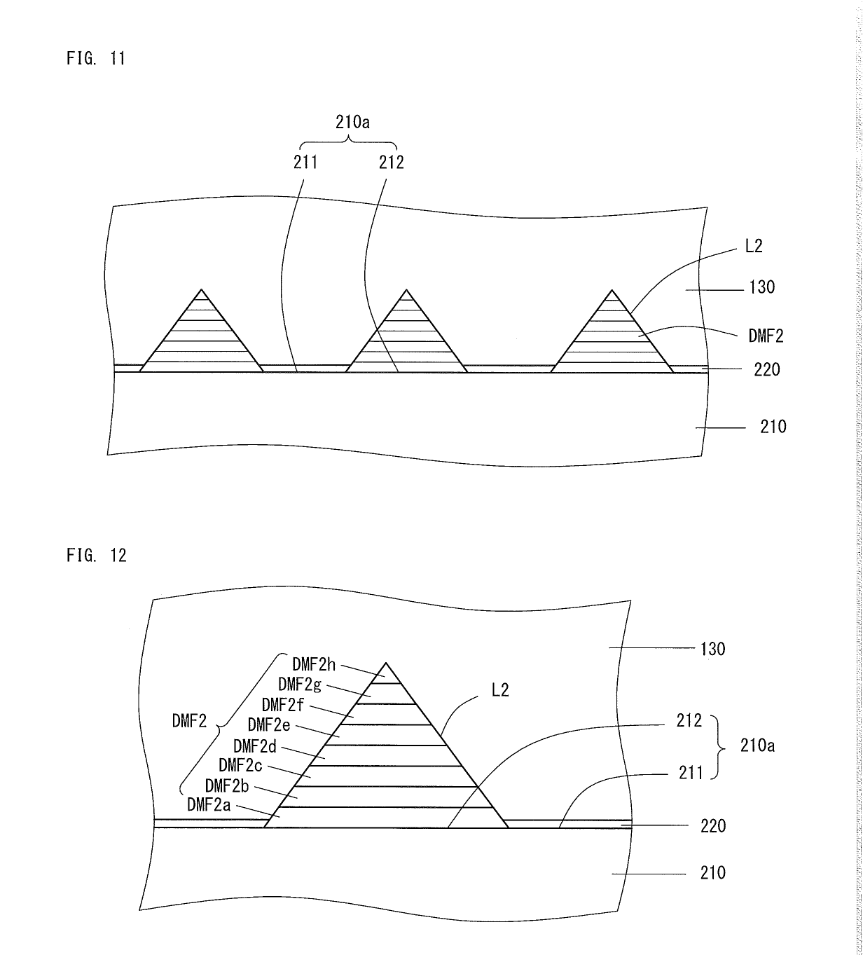

FIG. 11 is an enlarged view showing a part of the vicinity of the substrate 210. As shown in FIG. 11, the substrate 210 has the first surface 210a. The first surface 210a is flat over the entire surface thereof. That is, the substrate 210 has no uneven structure on the first surface 210a on the semiconductor layer side.

The first surface 210a has a first flat portion 211 and a plurality of second flat portions 212. The first flat portion 211 and the second flat portions 212 are disposed on the same plane. The first flat portion 211 is a part of the flat first surface 210a. The second flat portion 212 is the remaining portion of the flat first surface 210a. The buffer layer 220 is formed on the first flat portion 211. The dielectric multilayer films DMF2 are formed on the second flat portions 212. Therefore, the buffer layer 220 is not disposed on the dielectric multilayer films DMF2.

### 3. Dielectric Multilayer Film

The dielectric multilayer films DMF2 are formed on the second flat portions 212. The dielectric multilayer films DMF2 are a plurality of protrusions protruding to the n-type semiconductor layer 130. Each of the dielectric multilayer films DMF2 has a conical shape.

Each of the dielectric multilayer films DMF2 has an inclined side plane L2. The inclined side plane L2 is a conical surface. The inclined plane L2 is an inclined plane inclined to the first surface 210a. An angle of the inclined plane L2 to the first surface 210a is within a range of 40° to 60°. The angle is not limited to this range.

FIG. 12 is an enlarged view showing a part of the vicinity of the dielectric multilayer film DMF2. The dielectric multilayer film DMF2 is a Distributed Bragg Reflector (DBR). The dielectric multilayer film DMF2 comprises dielectric films DMF2a, DMF2b, DMF2c, DMF2d, DMF2e, DMF2f, DMF2g, DMF2h, and so on. The dielectric films DMF2a, DMF2c, DMF2e, and DMF2g are formed of the same material, for example, TiO₂. The dielectric films DMF2b, DMF2d, DMF2f, and DMF2h are formed of the same material, for example, SiO₂, which is different from the material of the dielectric films DMF2a, DMF2c, DMF2e, and DMF2g.

### 4. Effects of Dielectric Multilayer Film

### 4-1. Transmission and Reflection in Dielectric Multilayer Film

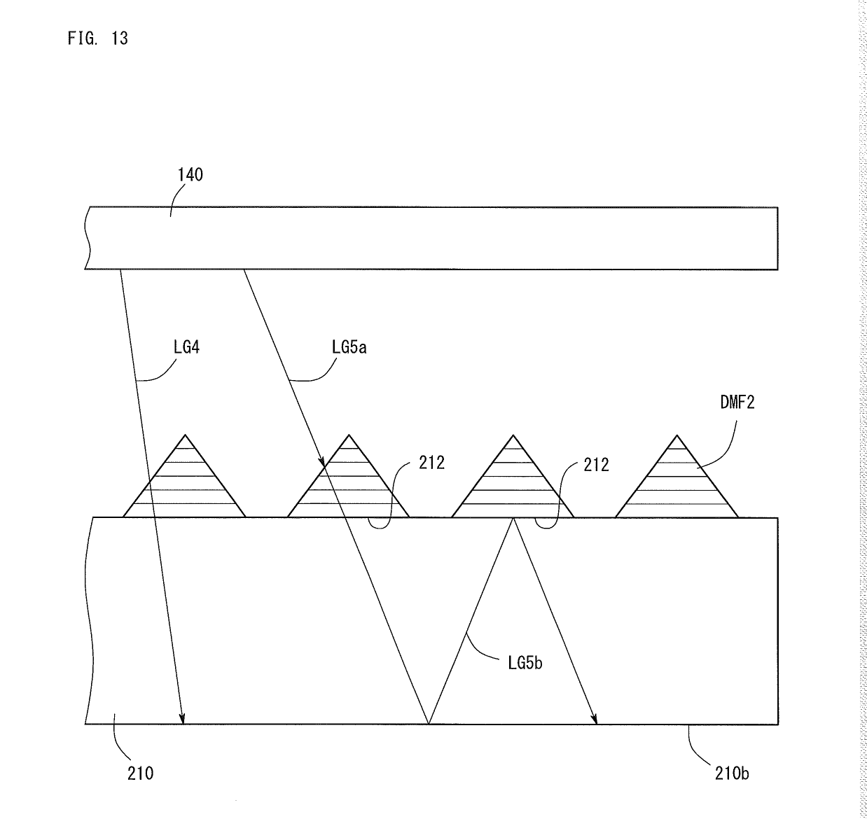

FIG. 13 is a view showing the concepts of reflection and transmission in the vicinity of the dielectric multilayer film DMF2 in the light-emitting device 200. The substrate 210, the dielectric multilayer film DMF2, and the light-emitting layer 140 are extracted from the constituent elements of the light-emitting device 200, and shown in FIG. 13. A light LG4 directed from the light-emitting layer 140 toward the substrate 210 passes through the dielectric multilayer film DMF2 and is incident to the substrate 210 as shown in FIG. 13. The light LG4 is emitted from the second surface 210b to an outside.

A light LG5a directed from the light-emitting layer 140 toward the first surface 210a of the substrate 210, firstly passes through the dielectric multilayer film DMF2, and is incident to the second flat surface 212 of the substrate 210, and reflected at the second surface 210b the substrate 210. A light LG5b reflected by the second surface 210b is directed from the second surface 210b of the substrate 210 toward the light-emitting layer 140. The light LG5b is reflected by the bottom surface of another dielectric multilayer film DMF2, i.e., the flat second surface 212, and is directed toward the second surface 210b again.

Moreover, like the light LG3a shown in FIG. 4, some lights are reflected once by the inclined side surface L2 of the dielectric multilayer film DMF2, and the reflected lights are incident in the inclined side surface L2 of another DMF2 and are incident to the substrate 210. Therefore, the emission efficiency of the light-emitting device 200 is high.

### 5. Method of Preparing Substrate

### 5-1. Substrate Preparation Step

The step of preparing the substrate 210 of Embodiment 2 is described. Firstly, there is provided a substrate 210 shown in FIG. 14. The substrate 210 has a flat first surface 210a and a flat second surface 210b. The first surface 210a is flat over the entire surface thereof.

### 6. Method of Forming a Dielectric Multilayer Film

### 6-1. Film Formation Step

As shown in FIG. 15, a dielectric multilayer film DMF2i is formed on the first surface 210a of the substrate 210. At this stage, a uniform dielectric multilayer film DMF2i is formed over the entire surface of the first surface 210a of the substrate 210. The surface of uniform dielectric multilayer film DMF2i is flat. The number of uniform dielectric multilayer films DMF2i is 1, that is, the DMF2i is continuous.

### 6-2. Resist Disposition Step

As shown in FIG. 16, a plurality of resists R1 is formed on the uniform dielectric multilayer film DMF2i. These resists R1 are disposed in positions where a plurality of dielectric multilayer films DMF2 is formed.

### 6-3. Etching Step

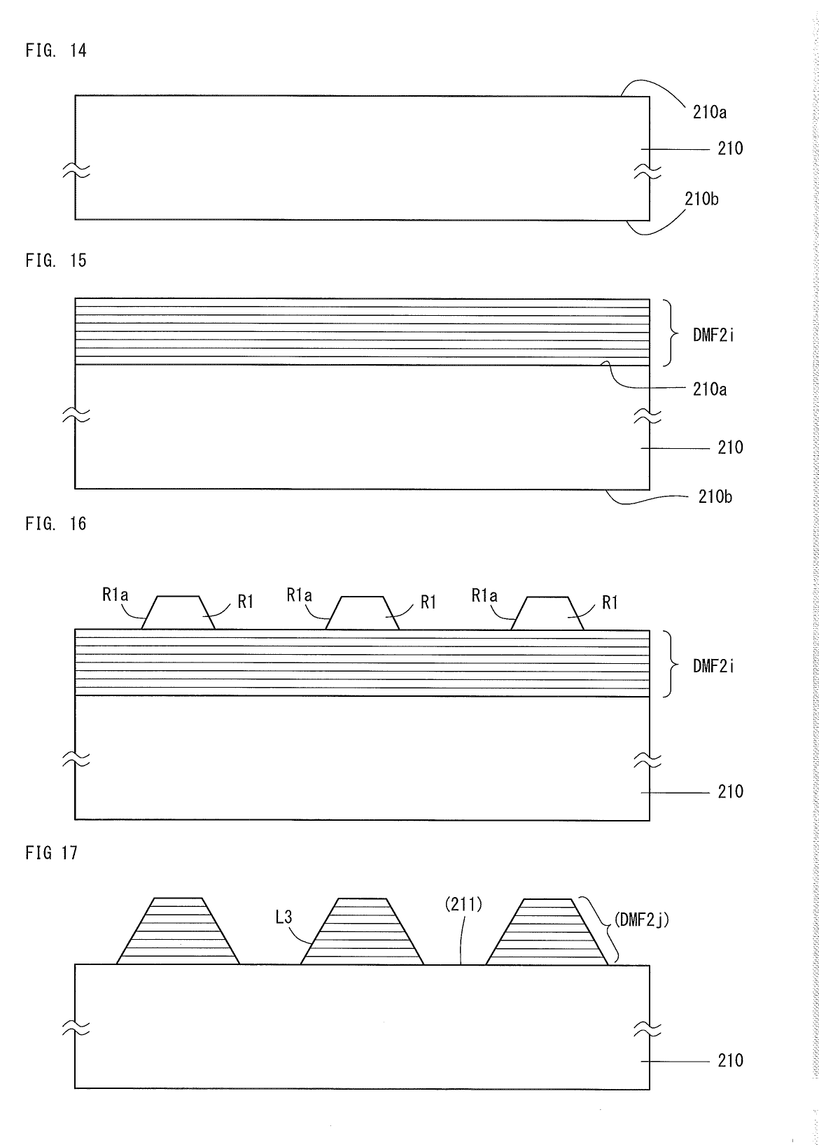

Subsequently, the uniform dielectric multilayer film DMF2i on the substrate 210 is etched. Etching proceeds from the portions which are not covered with the resists R1. FIG. 17 shows a state in the middle of etching. In FIG. 17, the resists R1 have disappeared, and inclined planes L3 are formed. As etching further proceeds, the inclined planes L3 become the inclined planes L2. While the inclined planes L2 are formed, a plurality of dielectric multilayer films DMF2 is formed from the uniform dielectric multilayer film DMF2i. As etching proceeds, the first surface 210a of the substrate 210 is partially exposed. The thus-exposed portion corresponds to the first flat portion 211.

Needless to say, etching may be finished in the state shown in FIG. 17. In that case, the dielectric multilayer film DMF2j has a truncated cone shape. A desired shape of a plurality of dielectric multilayer films DMF2 is obtained by etching, considering the shape of the resist R1, the etching time, and others.

### 7. Method for Producing a Semiconductor Light-Emitting Device

The method for producing the semiconductor light-emitting device according to Embodiment 2, same as in Embodiment 1, has a substrate preparation step, a dielectric multilayer film formation step, a buffer layer formation step, a first semiconductor layer formation step, a light-emitting layer formation step, a p-type semiconductor layer formation step, and an electrode formation step.

### 7-1. Dielectric Multilayer Film Formation Step

A plurality of dielectric multilayer films DMF2 is formed on the second flat surface 212 of the substrate 210 by performing the film formation step, the resist disposition step, and the etching step to the substrate 210 prepared in the aforementioned substrate preparation step. Through etching, the first flat portion 211 is exposed.

7-2. Buffer layer formation step

Next, a buffer layer 220 is formed on the first flat portion 211 partially exposed.

### 7-3. Other Steps

Performing the first semiconductor layer formation step, the light-emitting layer formation step, the p-type semiconductor layer formation step, and the electrode formation step after the buffer layer formation step is same as in Embodiment 1.

### 8. Variation

Variation of Embodiment 1 can be used accordingly.

### 9. Summary of Embodiment 2

As described hereinabove, the light-emitting device 200 according to Embodiment 2 has a substrate 210 and a plurality of dielectric multilayer films DMF2. The dielectric multilayer film DMF2 is a Distributed Bragg Reflector (DBR). The dielectric multilayer film DMF2 transmits more light, which is directed from the semiconductor layer toward the first flat surface 212, into the substrate 210, and the bottom surface of the MDF2 reflects more light, which is directed from the second surface 210b of the substrate 210 toward the semiconductor layer, to the second surface 210b. Therefore, a light once emitted from the semiconductor layer to the substrate 210 is hardly incident to the semiconductor layer again. This achieves a light-emitting device 200 which attains suitable light extraction from the light extraction surface.

In the method for producing the semiconductor light-emitting device according to Embodiment 2, a semiconductor layer is grown from the bottom surface 211 where the dielectric multilayer film DMF2 is not formed.

The aforementioned embodiment is merely an example. It is therefore understood that those skilled in the art can provide various modifications and variations of the technique, so long as those fall within the scope of the present technique. The layered structure of the layered product should not be limited to those as illustrated, and the layered structure, the number of repetition of component layers, and other factors may be arbitrarily chosen. The semiconductor layer growth technique is not limited to metalorganic chemical vapor deposition (MOCVD), and other techniques such as hydride vapor phase epitaxy (HVPE) and other liquid-phase epitaxy techniques may also be employed.

What is claimed is:

1. A Group III nitride semiconductor light-emitting device comprising:
a substrate having a first surface;
a buffer layer disposed on at least a part of the first surface of the substrate;
a first conduction type first semiconductor layer disposed on the buffer layer;
a light-emitting layer disposed on the first semiconductor layer; and
a second conduction type second semiconductor layer on the light-emitting layer;
wherein a plurality of dielectric multilayer films are provided on the first surface side of the substrate;
the first surface of the substrate has at least a flat surface;
the buffer layer is formed on at least a part of the flat surface;
each of the dielectric multilayer films has an inclined plane inclined to the flat surface; and
the first semiconductor layer is formed on the buffer layer and the inclined planes of the dielectric multilayer films.

2. A Group III nitride semiconductor light-emitting device according to claim 1, wherein the first surface of the substrate has a plurality of protrusions, the dielectric multilayer films cover at least a part of the surfaces of the protrusions, and a portion other than the protrusions on the first surface of the substrate is a flat surface.

3. A Group III nitride semiconductor light-emitting device according to claim 1, wherein the first surface of the substrate is the flat surface over an entire surface of the first surface, the buffer layer is formed on a part of the flat surface, and the dielectric multilayer films are formed on the remaining part of the flat surface, which are a plurality of protrusions protruding toward the first semiconductor layer.

4. A Group III nitride semiconductor light-emitting device according to claim 1, wherein the dielectric multilayer films are a plurality of Distributed Bragg Reflectors (DBR).

5. A Group III nitride semiconductor light-emitting device according to claim 2, wherein the dielectric multilayer films are a plurality of Distributed Bragg Reflectors (DBR).

6. A Group III nitride semiconductor light-emitting device according to claim 3, wherein the dielectric multilayer films are a plurality of Distributed Bragg Reflectors (DBR).

7. A Group III nitride semiconductor light-emitting device according to claim 1, wherein the buffer layer is not disposed on the dielectric multilayer films.

8. A Group III nitride semiconductor light-emitting device according to claim 1, wherein the Group III nitride semiconductor light-emitting device is a flip-chip type light-emitting device, and the substrate has a roughened second surface.

9. A method for producing a Group III nitride semiconductor light-emitting device comprising steps of:
preparing a substrate having at least a flat surface on a first surface;
forming a buffer layer on at least a part of the flat surface;
forming a first conduction type first semiconductor layer on the buffer layer;
forming a light-emitting layer on the first semiconductor layer; and
forming a second conduction type second semiconductor layer on the light-emitting layer;
wherein there is a forming a plurality of dielectric multilayer films on the first surface of the substrate;
in the forming the dielectric multilayer film, the dielectric multilayer films are formed so as to have inclined planes inclined to the flat surface;
in the forming the buffer layer, the buffer layer is grown on the flat surface of the substrate which is not covered with the dielectric multilayer film; and
in the forming the first semiconductor layer, the first semiconductor layer is formed on the buffer layer so as to cover the inclined planes of the dielectric multilayer films.

10. The method for producing the Group III nitride semiconductor light-emitting device according to claim 9, wherein in the preparing the substrate, there is prepared a substrate having an uneven structure in which the first surface comprises the flat surface and a plurality of protrusions;
the forming the dielectric multilayer film comprises steps of:
forming a mask on the flat surface;
forming a dielectric multilayer film on the protrusions and the mask; and
removing the mask from the flat surface to obtain a plurality of dielectric multilayer films on the protrusions.

11. The method for producing the Group III nitride semiconductor light-emitting device according to claim 9, wherein in the preparing the substrate, the flat surface is over the entire surface of the first surface;
the forming the dielectric multilayer film comprises steps of:
forming a uniform dielectric multilayer film on the flat surface;
disposing a resist mask with a predetermined pattern on the uniform dielectric multilayer film; and
etching the uniform dielectric multilayer film to form the inclined planes, thereby being made into a plurality of dielectric multilayer films and to partially expose the flat surface of the substrate; and
in the forming the buffer layer, the buffer layer is formed on the flat surface partially exposed.
